(19) United States
(12) Patent Application Publication
(10) Pub. No.: US 2014/0102536 A1
(43) Pub. Date: Apr. 17, 2014

(54) Composite Metallic Solar Cells

(71) Applicant: Nanosensing Technologies, Inc., Panama City (PA)

(72) Inventors: Patricia Maria Albuquerque de Farias, Recife (BR); Arnaldo Cesar Dantas dos Santos Andrade, Recife (BR); Josivandro do Nascimento Silva, Recife (BR); Jamil Saade, Recife (BR); Olavo Dhyan de Farias Cardozo, Recife (BR)

(73) Assignee: Nanosensing Technologies, Inc., Panama City (PA)

(21) Appl. No.: 13/840,183

(22) Filed: Mar. 15, 2013

Related U.S. Application Data
(60) Provisional application No. 61/612,058, filed on Mar. 16, 2012.
(60) Provisional application No. 61/621,958, filed on Apr. 9, 2012.
(60) Provisional application No. 61/658,311, filed on Jun. 11, 2012.

(51) Int. Cl. H01L 31/0216

(52) U.S. Cl. CPC H01L 31/02168; Y10S 977/774; Y10S 977/948; B82Y 99/00
USPC 136/259; 438/69; 977/774; 977/948

(57) ABSTRACT

A composite photovoltaic cell comprised of a substrate overlaid with metallic nanoparticles sensitized with quantum dots. Using flexible or rigid substrates in conjunction with metallic nanoparticles and quantum dots a highly efficient photovoltaic cell can be formed by using localized surface plasmon resonance. The localized surface plasmon resonance of the metallic nanoparticles enhances the absorption of photons and is further sensitized by quantum dots.

### RELATED APPLICATION

The present application relates to and claims the benefit of priority to U.S. Provisional Patent Applications No. 61/612,058 filed 16 Mar. 2012, No. 61/621,958 filed 9 Apr. 2012 and 61/658,311 filed 11 Jun. 2012, all of which are hereby incorporated by reference in their entirety for all purposes as if fully set forth herein.

### BACKGROUND OF THE INVENTION

1. Field of the Invention

Embodiments of the present invention relate, in general, to photovoltaic cells and more particularly to photovoltaic cells based on composite metallic and semiconductor material substrates enhanced with metallic nano-particles.

2. Relevant Background

A photovoltaic device or solar cell converts light to electricity. In such a device light shines onto an active layer and the interaction of the light with the components of the active layer generates an electrical current, converting light to electricity. The active layer can comprise a component that carries positive charge (or “holes”) and a second component that carries negative charge, (or “electrons”) and a junction between the two components. It is the junction between these components that allows or facilitates the conversion of light to electricity. The electric current can be picked up by electrodes on each side of the device and can be used to power something. In the photovoltaic device of this type, one side of the active layer is typically transparent to allow light through to the active layer. The opposite side can have reflective elements to reflect light back to the active layer so as to maximize active layer/light interaction.

In a conventional solar cell, light is absorbed by a semiconductor (the active layer) producing an electron-hole (e-h) pair. This pair is separated by an internal electric field and, as described above, the resulting flow of electrons and holes creates electric current. The internal electric field is created by doping one part of semiconductor with atoms which act as electron donors (n-type doping) and another with electron acceptors (p-type doping) that results in a p-n junction. Generation of e-h pair requires that the photons of light have energy exceeding the bandgap of the material. Whereas low energy photons produce negligible amount of e-h pairs, the numerous e-h pairs associated with higher energy photons are relatively inefficient: that is they produce an energetic e-h pair which quickly (within about 10-13 s) loses its energy through collisions with the lattice (“thermalizes”). As a result, most photon energy in a solar cell is lost into heat that lowers the conversion efficiency of light into electricity. Accordingly, the efficiency of a solar cell composed of a single material cannot, theoretically, exceed 31% efficiency.

It is possible to greatly improve on a single junction cell by stacking extremely thin cells with different bandgaps on top of each other using a “tandem cell” or “multi-junction” approach. The same basic analysis shows that a two layer cell can have a theoretical performance of 44% while a three-layer cell should be able to achieve an efficiency of 48%. An “infinity-layer”” cell can theoretically have an efficiency of 86%, with other loss mechanisms accounting for the remaining 14%.

Unfortunately, silicon preparation methods do not lend themselves to this multi-layer approach. There has, as an alternative, been some progress using thin-films of amorphous silicon, but other issues have prevented these from matching the performance of traditional cells. Quantum dot solar cells are also an emerging field in solar cell research that uses quantum dots as the photovoltaic material, as opposed to better-known bulk materials such as silicon, copper indium gallium selenide (CIGS) or CdTe. Quantum dots are particles of semiconductor material with the size so small that, due to quantum mechanics considerations, the electron energies that can exist within them are limited. Stated simply, quantum dots are semiconductors whose electronic characteristics are closely related to the size and shape of the individual crystal. Generally, the smaller the size of the crystal, the larger the bandgap, the greater the difference in energy between the highest valence band and the lowest conduction band becomes, therefore more energy is needed to excite the dot, and concurrently, more energy is released when the crystal returns to its resting state.

The bandgaps of quantum dots are tunable across a wide range of energy levels. This can be done by changing the quantum dot size. This is in contrast to bulk materials, where the bandgap is fixed by the choice of material composition. This property makes quantum dots attractive for multi junction solar cells, where a variety of different energy levels are used to extract more power from the solar spectrum.

The potential performance of the quantum dot approach has led to widespread research in the field. Early examples used costly molecular beam epitaxy processes, but alternative inexpensive fabrication methods have been developed. Some of these attempts rely on quantum dot synthesis using wet chemistry (Colloidal Quantum Dots—CQDs) and subsequent solution process-ability of quantum dots.

The ability to tune the bandgap is what makes them desirable for solar cell use. In this respect they are similar to the existing expensive GaAs tandem cells, and in theory have efficiencies on the same order. But quantum dots can improve this further. In particular, lead sulfide (PbS) quantum dots have bandgaps that can be tuned into the far infrared, energy levels that are normally unseen to traditional materials. For example, half of all the solar energy reaching the Earth is in the infrared, most of it in the near infrared region. With a quantum dot solar cell, IR-sensitive materials are just as easy to use as any other, opening the possibility of capturing much more energy cost-effectively.

Moreover, quantum dots are far easier to make than GaAs materials, and in some cases even simpler than traditional silicon. When suspended in a colloidal liquid form quantum dots can be easily handled throughout production, with the most complex equipment needed being a fume hood while the solvents outgas. The entire production process takes place at room temperature or on a hotplate, dramatically reducing handling issues and energy input. Although the base semiconductor material might require a complex preparation before being made into dots, the material does not have to be produced in large blocks, significantly reducing operational costs. Further the dots can be distributed on a substrate through spin coating, either by hand or in an easily automated process. In large-scale production, this technique could be replaced by spray-on or roll-printing systems, which dramatically reduces module construction costs.

As previously mentioned, there are significant problems with the currently available technologies related to solar cells. Crystalline silicon solar cells which have >90% market share today are very expensive. While environmentally friendly, the ultimate energy cost per kilowatt hour (kwh) for solar energy using current technology is more than twice that of the cost per kwh for fossil fuels. In addition, the capital cost of installing and maintaining solar panels is extremely high limiting its adoption rate. To achieve widespread adoption, the next generation of solar cells must achieve high efficiencies with light weight and low cost. Quantum dot based solar cells enhanced with nanoparticles of the present invention provides a potential solution to these, and other challenges of the prior art.

Additional advantages and novel features of this invention shall be set forth in part in the description that follows, and in part will become apparent to those skilled in the art upon examination of the following specification or may be learned by the practice of the invention. The advantages of the invention may be realized and attained by means of the instrumentalities, combinations, compositions, and methods particularly pointed out in the appended claims.

### SUMMARY OF THE INVENTION

An object of the present invention is to provide a method and apparatus for enhanced solar energy harvesting for power generation. For this purpose, in one embodiment of the present innovation, a unique optical property of metallic nanoparticles termed localized surface plasmon resonance (LSPR) is exploited.

According to one embodiment of the present invention, a substrate is covered with metallic nanorods and excitation of localized surface plasmons (charge density oscillations) by an electric field at an incident wavelength that results in strong light scattering, in the appearance of intense surface plasmon absorption bands and in an enhancement of the local electromagnetic fields. Quantum dots, in another embodiment, are deposited over the metallic nanorods that cover the substrate and, upon interaction of the substrate's surface with solar radiation, the absorption of light is further enhanced.

The features and advantages described in this disclosure and in the following detailed description are not all-inclusive. Many additional features and advantages will be apparent to one of ordinary skill in the relevant art in view of the drawings, specification, and claims hereof. Moreover, it should be noted that the language used in the specification has been principally selected for readability and instructional purposes and may not have been selected to delineate or circumscribe the inventive subject matter; reference to the claims is necessary to determine such inventive subject matter.

### BRIEF DESCRIPTION OF THE DRAWINGS

The aforementioned and other features and objects of the present invention and the manner of attaining them will become more apparent, and the invention itself will be best understood, by reference to the following description of one or more embodiments taken in conjunction with the accompanying drawings, wherein:

FIG. 1 shows, according to one embodiment of the present invention, a graph of reflectance spectra obtained for Micro-Crystalline Silicon solar cells with an overlaid layer of Gold nanorods, an organic fiber substrate covered with Gold nanorods (Au NRDs), Commercial glass covered with Silicon thin film sensitized with CdTe/CdS quantum dots, Micro-crystalline Silicon sensitized with CdTe/CdS quantum dots, and Organic Fiber covered by Gold nanorods sensitized with CdTe/CdS quantum dots;

FIG. 2 depicts a comparative graph of averaged and normalized absorbance spectra obtained for Micro-crystalline Silicon solar cells with no enhancements, Commercial glass overlaid with Gold nano-rods and covered with Silicon thin film sensitized with CdTe/CdS quantum dots, and Organic Fiber covered by Gold nanorods sensitized with CdTe/CdS quantum dots, according to one embodiment of the present invention;

FIG. 3 shows a graph of absorbance spectra of a substrate treated with Gold nanorods and Gold nanorods with CdTe/CdS Quantum Dots according to one embodiment of the present invention;

FIG. 4 is a high level flowchart of a method embodiment according to the present invention for the fabrication of a solar cell using composite nano rod metallic materials sensitized with quantum dots.

The Figures depict embodiments of the present invention for purposes of illustration only. One skilled in the art will readily recognize from the following discussion that alternative embodiments of the structures and methods illustrated herein may be employed without departing from the principles of the invention described herein.

### DESCRIPTION OF THE INVENTION

A composite photovoltaic cell comprised of a substrate overlaid with metallic nanoparticles that are sensitized with quantum dots is hereafter described by way of example. According to one embodiment of the present invention, a flexible or rigid substrate of a variety of compositions can be used in conjunction with metallic nanoparticles and quantum dots to form a highly efficient photovoltaic cell. The present invention utilizes localized surface plasmon resonance of metallic nanoparticles to enhance the absorption of photons by, in one embodiment, quantum dots. In other embodiments metallic nanoparticles and their associated localized surface plasmon resonance enhances the absorption characteristics of existing photovoltaic cells.

The following description with reference to the accompanying drawings is provided to assist in a comprehensive understanding of exemplary embodiments of the present invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

Unless defined herein, the terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purposes only and not for the purpose of limiting the invention as defined by the appended claims and their equivalents.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

Like numbers refer to like elements throughout. In the figures, the sizes of certain lines, layers, components, elements or features may be exaggerated for clarity. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. As used herein, the term “and/or” includes any and all combinations of one or more of the associated listed items.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

The term “nanoparticle” is defined as a small object that behaves as a whole unit with respect to its transport and properties. Coarse particles cover a range between 10,000 and 2,500 nanometers. Fine particles are sized between 2,500 and 100 nanometers. Ultra-fine particles, or nanoparticles, are sized between 100 and 1 nanometers.

A “nanorod” is a morphology of nanoparticles in which each dimension ranges from 1-100 nm. They may be synthesized from metals or semiconducting materials. Standard aspect ratios (length divided by width) are 3-5. Nanorods are typically produced by direct chemical synthesis.

“Quantum dots” are semiconductors whose electronic characteristics are closely related to the size and shape of the individual crystal. Generally, the smaller the size of the crystal, the larger the band gap, the greater the difference in energy between the highest valence band and the lowest conduction band becomes, therefore, more energy is needed to excite the dot, and concurrently, more energy is released when the crystal returns to its resting state.

It will be understood that when an element is referred to as being “on,” “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under,” “below,” “lower,” “over,” “upper” and the like, may be used herein for ease of description to describe one element or feature's relationship to another element(s) or feature(s) as illustrated in the figures. It will be understood that the spatially relative terms are intended to encompass different orientations of a device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of “over” and “under.” The device may be otherwise oriented (rotated 90 degrees or at other orientations) and the spatially relative descriptors used herein interpreted accordingly. Similarly, the terms “upwardly,” “downwardly,” “vertical,” “horizontal,” and the like are used herein for the purpose of explanation only unless specifically indicated otherwise.

Also included in the description are flowcharts depicting examples of the methodology which may be used to detect the presence of cTnI in a patient blood sample. The blocks of the flowchart illustrations support combinations of means for performing the specified functions and combinations of steps for performing the specified functions. It will also be understood that each block of the flowchart illustrations, and combinations of blocks in the flowchart illustrations, can be implemented by special purpose hardware including hardware-based computer systems that perform the specified functions or steps, or combinations of special purpose hardware and computer instructions.

As used herein, any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

As used herein, the terms “comprises,” “comprising,” “includes,” “including,” “has,” “having,” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise. Thus, for example, reference to “a component surface” includes reference to one or more of such surfaces.

According to one embodiment of the present invention a composite photovoltaic cell is comprised of a substrate overlaid with a metallic nanoparticles and sensitized with quantum dots. The metallic nanoparticles utilized in the present invention can be of a variety of different shapes including cubes, tubes, rods, spheres, and any other geometric shapes as would be known to one of reasonable skill in the relevant art. In one embodiment of the present invention, metallic nanorods are deposited on the substrate to promote the absorption of light by a photovoltaic using plasmonic resonance.

According to one embodiment of the present invention, plasmon resonance assists to scatter and trap light within the substrate so as to enhance the absorption of light by effectively increasing the optical path length of the light as it interacts with a photovoltaic. According to another embodiment of the present invention plasmon resonance associated with metallic nanoparticles results in a near-field effect that creates electron-hole pairs in the associated semiconductor/photovoltaic cell.

Light scattering is, in general, the attenuation of a beam of light by particles, either by absorption or scattering. When metallic nanoparticles are subjected with light the corresponding e-field causes the collective electron cloud of the nano particle to oscillate. Depending on the geometry and size of metallic nanoparticles the near field can be enhanced to different degrees and by different wavelengths. Said differently, by controlling the size and shape of the nanoparticle the effective degree and interaction wavelength can be manipulated. The increased e-field intensity in the semiconductor adjacent to the nanoparticle can result in increased absorption due to excited plasmons.

As previously discussed, current solar cell technology relies on silicon substrates that are relatively thick in order to absorb enough light to produce energy. Current methods are inefficient and are associated with high cost making it inadequately capable of competing with fossil fuels. The enhancement properties of metallic nanoparticles renders existing and new technology with respect to solar cells economically and technically feasible. Specifically, utilizing Localized Surface Plasmon Resonance (LSPR) can enhance the incident light to thereafter increase the absorption efficiency of any solar cell.

Light-matter interactions in which materials possess a negative real and small positive imaginary dielectric constant capable of supporting surface plasmon resonance (SPR) is know as surface plasmonic resonance. This resonance is a coherent oscillation of the surface conduction electrons excited by electromagnetic (EM) radiation, aka, light.

Propagated surface plasmon resonance (PSPR) relates to a phenomenon when an incidence light emitted from a light source reaches the surface of a metal film at a fixed incident angle. In such an instance, the light intensity reflected from a surface of the metal film picked up by a photo detector is approaching zero, i.e., the reflectance of the metal film is approaching zero while the light beam not reflected propagates at a given speed in a direction along the interface and excites the plasmon on the surface of the metal film to resonate. However, light in a sample medium cannot naturally excite PSPR and a high refractive index prism or grating is required for coupling.

By comparison, Localized Surface Plasmon Resonance (LSPR) is defined as collective charge density oscillations restricted in the neighborhood of nano-particles excited by an electromagnetic field with a specific frequency. LSPR may be set without utilizing a prism or grating for light coupling. LSPR is a possible excited state of the metallic nano-particle electron system, which can be excited by photons or, equivalently, by an electromagnetic field of light incident on the particle.

LSPR excitation is a consequence of the inter-electronic (collective) interactions of the electrons combined with spatial confinement of the conduction band electron system within a conductive nanoparticle volume. An electron density wave is formed with a frequency/wavelength/energy that depends on the electronic structure of the nanoparticle, its geometry, size and dielectric environment.

According to one embodiment the present invention, metallic nanoparticles in the shape of nanorods are applied to the surface of a substrate that is incident to a source of light. The interaction of the light and the nanorods creates LSPR within the nanorods which enhances the absorption of light by the underlying substrate. The metallic rods are, in one embodiment, comprised of gold nanorods while in another embodiment silver nanorods are used. Other materials as would be known to one of reasonable skill in the art are also known. These nanorods vary in shape and size but possesses an aspect ratio, a longitudinal dimension versus transverse dimension, of approximately 3.5 to 5.5.

The antenna-like nanorods serves to increase material (photon) extinction for incident light resulting in enhanced local electromagnetic field near the nanoparticles at the surface plasmon resonance. Moreover, there is an enhanced scattering cross-section of off-resonant light again enhancing the absorption potential.

Another feature of the present invention is the inclusion of quantum dots with the association of the metallic nanoparticles. The quantum dots sensitize the metallic nanoparticles to enhance the plasmon resonance and photon extinction. Moreover the quantum dots, as semiconductors themselves, directly convert the light to electricity.

According to one embodiment of the present invention, the composite metallic solar cell is comprised of gold or silver nanorods and a semiconducting material such as core-shell Cadmium Telluride/Cadmium Sulfide (CdTe/CdS) quantum dots. This combination of nanorods and quantum dots is deposited on both rigid (Si, glass, glassy carbon, corundum, etc) and/or flexible (organic composites fibers) substrates to form a composite solar cell substrate. In one version of the present invention highly photo-stable water soluble quantum dots are vaporized over rigid and flexible substrates covered by metallic nanorods materials to form a highly efficient solar cell.

To better understand the interaction of the LSPR of the nanorods and the quantum dots consider that in a semiconductor crystal lattice of a quantum dot, the electrons are squeezed together, since no two nearby electrons can share exactly the same energy level leading to quantum confinement. This leads to the conclusion that the energy levels of a quantum dot is dependent on its size. When the size of the quantum dot is smaller than the critical characteristic length called the Exciton Bohr radius, the electrons crowding lead to the splitting of the original energy levels into smaller ones with smaller gaps between each successive level. Quantum dots that have radii larger than the Exciton Bohr radius are said to be in the ‘weak confinement regime’ and the ones that have radii smaller than the Exciton Bohr radius are said to be in the ‘strong confinement regime’. Thus, if the size of the quantum dot is small enough that the quantum confinement effects dominate (typically less than 10 nm), the electronic and optical properties change, and the fluorescent wavelength is determined by the size.

The fluorescence of the quantum dots is a result of exciting the valence electron with a certain energy(or wavelength) and the emission of lower energy in the form of photons as the excited electron returns to the ground state, combining with the hole. The energy of the emitted photon is determined by the size of the quantum dot due to quantum confinement effects. In a simplified model of the excitation, the energy of the emitted photon can be seen as a sum of the band gap energy between occupied level and unoccupied energy level, the confinement energies of the hole and the excited electron, and the bound energy of the exciton (the electron-hole pair):

An immediate optical feature of colloidal quantum dots is their color. While the material which makes up a quantum dot defines its intrinsic energy signature, the nanocrystal's quantum confined size is more significant at energies near the band gap. Thus quantum dots of the same material, but with different sizes, can emit light of different colors. The physical reason is the quantum confinement effect.

The larger the dot, the redder (lower energy) its fluorescence spectrum. Conversely, smaller dots emit bluer (higher energy) light. The coloration is directly related to the energy levels of the quantum dot. Quantitatively speaking, the bandgap energy that determines the energy (and hence color) of the fluorescent light is inversely proportional to the size of the quantum dot. Larger quantum dots have more energy levels which are also more closely spaced. This allows the quantum dot to absorb photons containing less energy, i.e., those closer to the red end of the spectrum. Recent articles in Nanotechnology and in other journals have begun to suggest that the shape of the quantum dot may be a factor in the coloration as well, but as yet not enough information is available. Furthermore, it was shown that the lifetime of fluorescence is determined by the size of the quantum dot. Larger dots have more closely spaced energy levels in which the electron-hole pair can be trapped. Therefore, electron-hole pairs in larger dots live longer causing larger dots to show a longer lifetime.

As with any crystalline semiconductor, a quantum dot's electronic wave functions extend over the crystal lattice. Similar to a molecule, a quantum dot has both a quantized energy spectrum and a quantized density of electronic states near the edge of the band gap.

According to one embodiment of the present invention, a CdTe/CdS quantum dot solution is formed in an aqueous medium by placing in round flask 0.2 mmol of Cd(ClO₄)₂ and mixing it with 20 ml of ultra-pure water and 1.5 mL of Mercapto-aceptic Acid (AMA) solution. In another embodiment a CdC₁₂ additive can be used to achieve the same result. The solution turves due to the partial solubility of the Cd²+-AMA complex. The pH is thereafter adjusted to 10.5 by adding NaOH. The resulting solution is injected in a round flask that contains Sodium Borohydrate (NaBH₄) and reduced Tellurium (Te²⁻). The formation of CdTe/CdS quantum dots immediately after the injection turns the solution a brown color indicating the formation of the Cd²⁺-AMA solution. This solution is then stored at 10° C. for approximately 48 hours before its introduction to a nano rod covered substrate.

As illustrated above, colloidal semiconductor nano-crystals are typically synthesized from precursor compounds dissolved in solutions, much like traditional chemical processes. The synthesis of colloidal quantum dots is based on a three-component system composed of precursors, organic surfactants, and solvents. When heating a reaction medium to a sufficiently high temperature, the precursors chemically transform into monomers. Once the monomers reach a high enough supersaturation level, the nanocrystal growth starts with a nucleation process. The temperature during the growth process is one of the factors in determining optimal conditions for the nanocrystal growth. It must be high enough to allow for rearrangement and annealing of atoms during the synthesis process while being low enough to promote crystal growth. Another factor that has to be stringently controlled during nanocrystal growth is the monomer concentration. At high monomer concentrations, the critical size (the size where nanocrystals neither grow nor shrink) is relatively small, resulting in growth of nearly all particles. In this regime, smaller particles grow faster than large ones (since larger crystals need more atoms to grow than small crystals) resulting in “focusing” of the size distribution to yield nearly monodisperse particles. The size focusing is optimal when the monomer concentration is kept such that the average nanocrystal size present is always slightly larger than the critical size.

There are colloidal methods to produce many different semiconductors. Typical dots are made of binary alloys such as cadmium selenide, cadmium sulfide, indium arsenide, and indium phosphide but other alloys are possible and contemplated as would be recognized by one of ordinary skill in the relevant art. Dots may also be made from ternary alloys such as cadmium selenide sulfide. These quantum dots can contain as few as 100 to 100,000 atoms within the quantum dot volume, with a diameter of 10 to 50 atoms.

Large batches of quantum dots may be economically synthesized via colloidal synthesis. Due to this scalability and the convenience of bench-top conditions, colloidal synthetic methods are promising for commercial applications.

The optical properties of the quantum dots across a spectra indicate (theoretically) a conversion efficiency higher than 35% for fiber composite substrate covered by gold nanorods sensitized with highly photo-stable CdTe/CdS Quantum Dots, while for Si and commercial glass covered by thin films of gold nanorods sensitized by CdTe/CdS Quantum Dots the conversion efficiency is approximately 41%.

According to another aspect of the present invention, metallic (Gold) nanorods are prepared via a colloidal chemistry method, by using salts as metallic precursors; in one embodiment of the present invention, a gold seed solution is prepared by adding 0.6 ml of ice-cold solution of 10 mM NaBH₄ to 10 mL of 0.25 mM HAuCl₄ prepared in 0.1 M CTAB solution, under vigorous stirring for 2 minutes. The formation of gold seeds is evidenced by the original yellow color changed immediately to brown. These seeds are thereafter aged for 2 hours in order to allow the hydrolysis of unreacted NaBH₄.

Solar cells described herein can be formed using several different types of substrates including common commercial glass and flexible organic fibers. Accordingly the present invention offers attractive opportunities of applications in distinct fields, such as: car coverage (minimizing fuel consumption); use as coverage of pre-existing solar cells/panels, increasing their efficiency in at least 300% (the present invention is at least three times more efficient than the already installed Silicon solar cells); wireless and autonomic streets illumination and signalization devices; nautical energy supplier, among others.

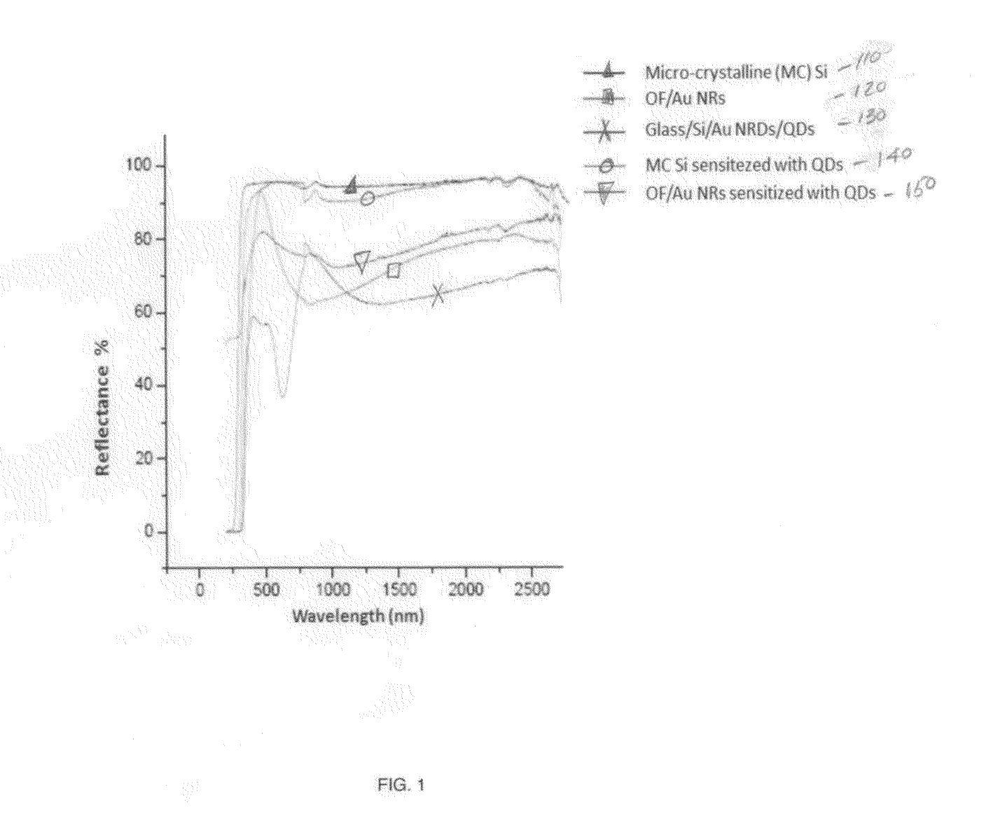

FIG. 1 shows a graph of reflectance spectra obtained for composite solar cells according to the present invention including Micro-Crystalline Silicon solar cells 110 overlaid with Gold nanorods, an organic fiber substrate covered with Gold nanorods 120, commercial glass 130 covered with Silicon thin film sensitized with CdTe/CdS quantum dots, Micro-crystalline Silicon sensitized with CdTe/CdS quantum dots 140, and organic fiber covered by Gold nanorods sensitized with CdTe/CdS quantum dots 150. As shown the reflectance of the Micro-Crystalline Silicon solar cells covered with gold nanorods is near 100% across a wide breadth of wavelengths as is the Micro-Crystalline Silicon solar cells sensitized with quantum dots. And while not possessing the same reflectance of the Micro-Crystalline Silicon solar cells, organic fibers covered by gold nanorods and sensitized with quantum dots achieves, for most wavelengths, reflectance greater than 60%.

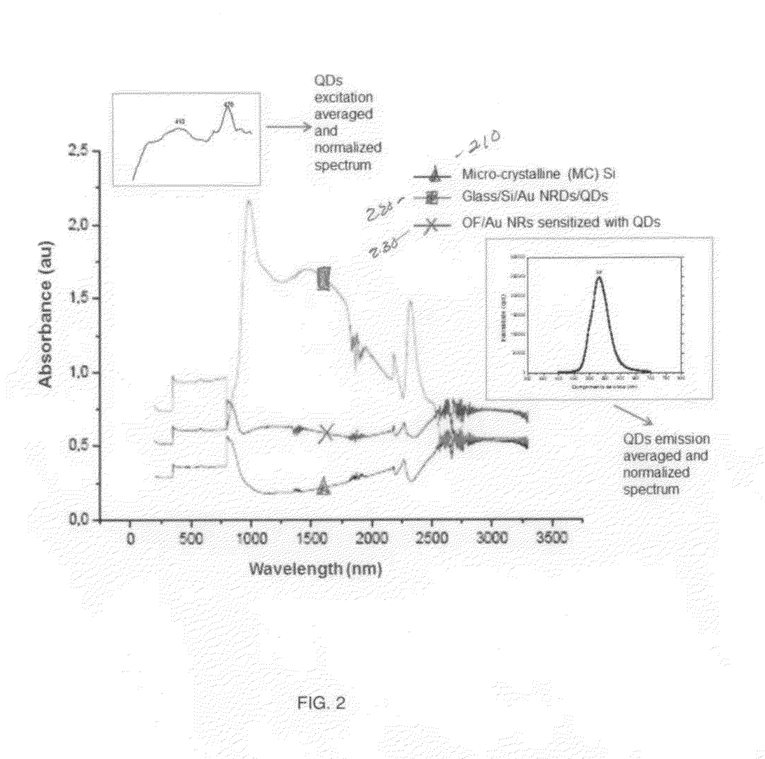

FIG. 2 shows a graph of averaged and normalized absorbance spectra obtained for composite metallic solar cells according to the present invention, including Micro-crystalline Silicon solar cells 210 with no enhancements, commercial glass covered with Silicon thin film overlaid with gold nan rods and sensitized with CdTe/CdS quantum dots 220, and Organic Fiber covered by Gold nanorods and sensitized with CdTe/CdS quantum dots 230. As shown the glass/Silicon substrate overlaid with gold nanorods and sensitized with quantum substantially absorbs more light than the Micro-Crystalline Silicon solar cell. Moreover, even an organic fiber substrate covered with Gold nanorods and sensitized with quantum dots out performs the Micro-Crystalline Silicon solar cell. These results solidify the absorption enhancing effect of Localized Surface Plasmon Resonance elicited by the metallic nanorods and the sensitizing effect of the quantum dots.

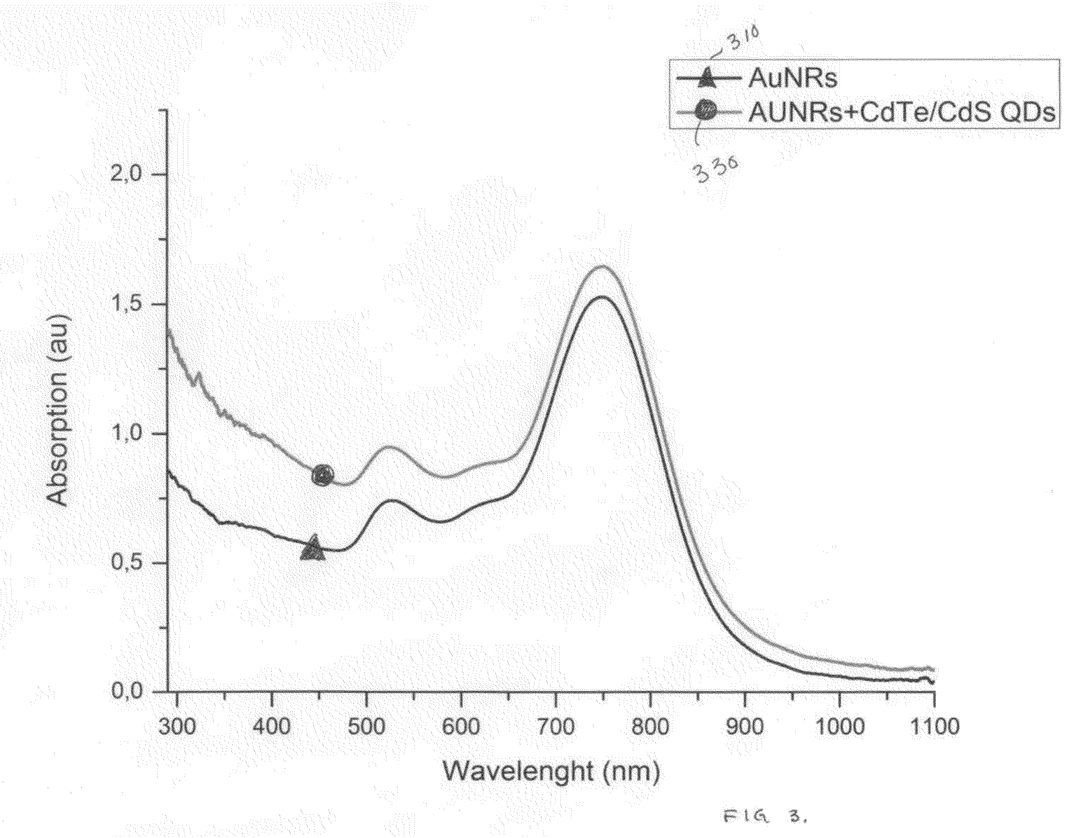

FIG. 3 depicts a comparative graph of absorbance spectra of a substrate treated with Gold nanorods 310 and a Gold nanorods with CdTe/CdS quantum dots. As can be seen, the substrate treated with Gold nanorods exhibits strong absorption of electromagnetic radiation in the UV (290-400 nm) region up to the near Infrared region(>700 nm up to 1100 nm) which is further enhanced by the presence of quantum dots.

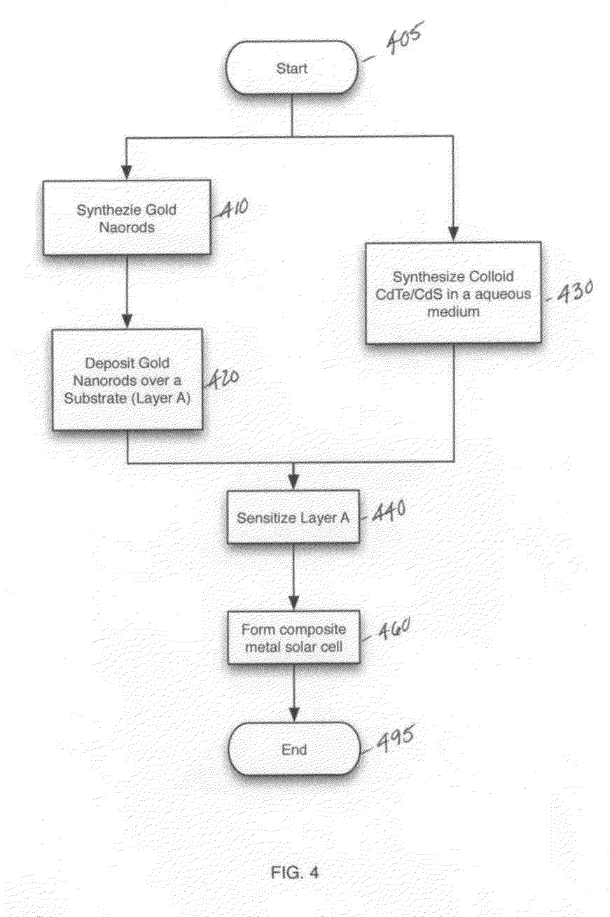

FIG. 4 shows a high level flowchart for one method embodiment the synthesis of a metallic composite based solar cell using metal nanorods according to the present invention. In the following description, it will be understood that each block of the flowchart illustrations, and combinations of blocks in the flowchart illustrations, can be implemented by various processes including processes aided by computer program instructions. These computer program instructions may be loaded onto a computer or other programmable apparatus to produce a machine such that the instructions that execute on the computer or other programmable apparatus create means for implementing the functions specified in the flowchart block or blocks. These computer program instructions may also be stored in a computer-readable memory that can direct a computer or other programmable apparatus to function in a particular manner such that the instructions stored in the computer-readable memory produce an article of manufacture including instruction means that implement the function specified in the flowchart block or blocks.

The blocks of the flowchart illustrations support combinations of means for performing the specified functions and combinations of steps for performing the specified functions. It will also be understood that each block of the flowchart illustrations, and combinations of blocks in the flowchart illustrations, can be implemented by special purpose hardware-based systems that perform the specified functions or steps, or combinations of special purpose hardware.

As is shown in FIG. 4 the process begins 405 with the synthesis of Gold Nanorods 410. According to one embodiment of the present invention Gold Nanorods are prepared via a colloidal chemistry method as described above however, as one of reasonable skill in the relevant art will appreciate, other methodology to synthesize gold (metallic) nanorods (nanoparticles) is both within the scope of and contemplated by the present invention.

Next, Gold nanorods are deposited 420 over a substrate. In one implementation a dry box is used to deposit the gold nanorods over distinct substrates (silica, glass, flexible organic polymer, etc.) by spraying for a period of time at room temperature forming a layer of nanorods. A commercial spray pump as would be known to of reasonable skill in the relevant art can be used as could other means that would provide for the even and control dispersant of a colloidal solution of nanoparticles.

At the same time and according to one embodiment of the present invention, a colloidal solution of CdTe/CdSl quantum dots is prepared 430. Thereafter, the deposited layer of nanorods is sensitized 440 by spraying the layer in a dry box with the CdTe/CdS aqueous medium for approximately for a period of time at room temperature. To prevent photo-corrosion, the obtained cells are covered 460 by antireflective glass, polyimide film or the like forming a composite metal solar cell ending the process 495.

According to another embodiment of the present invention, preexisting commercial silicon solar cells can also be modified and enhanced by the application of metallic nanoparticles and/or quantum dots. By doping existing silicon amorphous, polycrystalline, or micro-crystalline solar cells with metallic nanoparticles and/or quantum dots, increased efficiency of photon absorption can be obtained. According to one embodiment of the present invention, these nanoparticles can be bound or not bound to fluorescent molecules. The degree of increased efficiency and/or gain achieved by modifying existing silicon solar cells with nanoparticles of a distinct shape (such as nano discs, nanorods, nano spheres, nano prisms, nano cubes, and nano wires), size and dimensions as well as the composition (metallic, aluminum, gold, silver) that promotes LSPR and thereafter sensitizing them with quantum dots.

The embodiments of the present invention illustrated herein describe a process by which to make solar cells that are orders of magnitude more efficient. The enhanced efficiency applicable to all forms of solar cells enables a significant increase in power production in combination with substantial cost savings making photovoltaic power a more acceptable and feasible form of power generation.

Although the invention has been described and illustrated with a certain degree of particularity, it is understood that the present disclosure has been made only by way of example and that numerous changes in the combination and arrangement of parts can be resorted to by those skilled in the art without departing from the spirit and scope of the invention.

While there have been described above the principles of the present invention in conjunction with composite metal solar cells, it is to be clearly understood that the foregoing description is made only by way of example and not as a limitation to the scope of the invention. Particularly, it is recognized that the teachings of the foregoing disclosure will suggest other modifications to those persons skilled in the relevant art. Such modifications may involve other features that are already known per se and which may be used instead of or in addition to features already described herein. Although claims have been formulated in this application to particular combinations of features, it should be understood that the scope of the disclosure herein also includes any novel feature or any novel combination of features disclosed either explicitly or implicitly or any generalization or modification thereof which would be apparent to persons skilled in the relevant art, whether or not such relates to the same invention as presently claimed in any claim and whether or not it mitigates any or all of the same technical problems as confronted by the present invention. The Applicant hereby reserves the right to formulate new claims to such features and/or combinations of such features during the prosecution of the present application or of any further application derived therefrom.

1. A method for enhancing power generation by a photovoltaic cell, comprising:
covering a substrate with metallic nanorods;
depositing quantum dots over the metallic nanorods forming a composite photovoltaic cell having metallic nanorodes interposed between a substrate and quantum dots;
illuminating with a light source the substrate covered with nanorods and quantum dots, the substrate having an interaction surface oriented toward the light source; and
tuning the metallic nanorods and quantom dots to achieve localized surface plasmon resonance on the interaction surface to enhance absorption of light.

2. The method of claim 1, wherein the quantum dots are core shell Cadmium Telluride/Cadmium Sulfide (CdTe/CdS).

3. The method of claim 1, wherein the metallic nanorods are gold nanorods.

4. The method of claim 1, wherein the metallic nanorods are silver nanorods.

5. The method of claim 1, wherein the metallic nanorods have an aspect ratio greater than or equal to 3.5.

6. The method of claim 1, wherein the metallic nanorods have an aspect ratio less than or equal to 5.5.

7. The method of claim 1, further comprising coupling localized surface plasmon resonance of the plurality of nanorods with the interaction surface.

8. The method of claim 1, wherein the substrate is an organic fiber.

9. A plasmon enhanced photovoltaic cell, comprising:
a substrate;
a plurality of quantum dots deposited on the substrate;
a plurality of metallic nanorods interposed between the substrate and the quantum dots wherein the plurality of metallic nanorods are tuned to interact with a light source to form localized surface plasmon resonance (LSPR) and wherein the LSPR enhances the absorption of light by the quantum dots.

10. The plasmon enhanced photovoltaic cell of claim 9, wherein the substrate is mono-crystalline silicon.

11. The plasmon enhanced photovoltaic cell of claim 9, wherein the substrate is poly-crystalline silicon.

12. The plasmon enhanced photovoltaic cell of claim 9, wherein the metallic nanorods are gold nanorods.

13. The plasmon enhanced photovoltaic cell of claim 9, wherein the metallic nanorods are silver nanorods.

14. The plasmon enhanced photovoltaic cell of claim 9, wherein LSPR associated with the metallic nanorods forms electron-hole pairs in the quantum dots.

15. The plasmon enhanced photovoltaic cell of claim 9, wherein the substrate is an organic fiber.

16. The plasmon enhanced photovoltaic cell of claim 9, wherein the substrate is mono-crystalline silicon.

17. A method for enhancing absorption properties of a photovoltaic cell, comprising:
creating a localized surface plasmon resonance (LSPR) on a surface of a photovoltaic cell using metallic nanorods;
sensitizing the surface with Cadmium Telluride/Cadmium Sulfide quantum dots; and
tuning the LSPR to maximize electron-hole generation in the photovoltaic cell and enhance electron field density.

18. The method of claim 17, wherein the surface on which the LSPR is created is interposed between the photovoltaic cell and a light source.

19. The method of claim 17, wherein the metallic nanorods possess an aspect ratio no greater than 5.5.

20. The method of claim 17, wherein the metallic nanorods are gold nanorods.
